(19) United States
(12) Patent Application Publication
(10) Pub. No.: US 2026/0324248 A1
(43) Pub. Date: Oct. 15, 2026

(54) DISPLAY PANEL AND MANUFACTURING METHOD THEREFOR

(71) Applicants: Chengdu BOE Optoelectronics Technology Co., Ltd., Chengdu, Sichuan (CN); BOE Technology Group Co., Ltd., Beijing (CN)

(72) Inventors: Lihui LUO, Beijing (CN); Zhenye WEI, Beijing (CN); Qiyun WANG, Beijing (CN); Lulin MA, Beijing (CN); Xiao WANG, Beijing (CN)

(21) Appl. No.: 19/475,040

(22) PCT Filed: Oct. 22, 2024
(86) PCT No.: PCT/CN2024/126350

§ 371 Date: Oct. 13, 2025

(30) Foreign Application Priority Data
Nov. 29, 2023 (CN) 202311619307.5

(51) Int. Cl. H10K 59/80; H10K 59/12; H10K 59/122; H10K 71/60

(52) U.S. Cl. CPC H10K 59/80515; H10K 59/1201; H10K 59/122; H10K 59/80521; H10K 59/873; H10K 71/60

(57) ABSTRACT

The present application discloses a display panel and a manufacturing method therefor. The display panel includes a substrate, a planarization layer, and a light-emitting layer. The planarization layer is on the substrate. The light-emitting layer is on a side of the planarization layer away from the substrate, and includes a plurality of light-emitting structures arranged at intervals and a plurality of auxiliary electrodes. Each light-emitting structure includes a first electrode on the planarization layer, a luminescent material layer on a side of the first electrode away from the substrate, and a second electrode on a side of the luminescent material layer away from the substrate. The plurality of auxiliary electrodes are on the planarization layer and at least partially in direct contact with the planarization layer, and each auxiliary electrode is configured to connect second electrodes of two adjacent light-emitting structures. In the display panel described above, the manufacturing of the auxiliary electrode is facilitated by providing both the auxiliary electrode and the first electrode on the planarization layer, thereby reducing the impact on the first electrode while the auxiliary electrode is manufactured.

### TECHNICAL FIELD

The present disclosure relates to the field of display technology, and particularly relates to a display panel and a manufacturing method therefor.

### BACKGROUND

With the rapid development of science and technology, the OLED display panel has become the first choice for panels of display devices such as mobile phones and computers due to its advantages of fast response, high brightness, wide viewing angle, and the like. In the OLED display panel, a cathode generally employs a surface electrode having a larger area. The connection performance between cathodes of different subpixels directly affects the continuity of the cathodes and the display effect of the display panel.

### SUMMARY

The present application discloses a display panel, including:
a substrate;
a planarization layer on the substrate;
a light-emitting layer on a side of the planarization layer away from the substrate, including a plurality of light-emitting structures arranged at intervals and a plurality of auxiliary electrodes; wherein each light-emitting structure includes a first electrode on the planarization layer, a luminescent material layer on a side of the first electrode away from the substrate, and a second electrode on a side of the luminescent material layer away from the substrate; and the plurality of auxiliary electrodes are on the planarization layer and at least partially in direct contact with the planarization layer, and each auxiliary electrode is configured to connect second electrodes of two adjacent light-emitting structures.

In some embodiments, the auxiliary electrode is in a same layer as the first electrode; and
the auxiliary electrode is made of a same material as the first electrode.

In some embodiments, the planarization layer includes two undercut grooves partially under the auxiliary electrode and having openings at opposite sides of the auxiliary electrode; and ends of the second electrodes of the two adjacent light-emitting structures connected by the auxiliary electrode are in the two undercut grooves, respectively, and connected to the auxiliary electrode.

In some embodiments, the display panel includes a support top layer on a side of the auxiliary electrode away from the substrate, an orthographic projection of the auxiliary electrode in a thickness direction of the display panel is within an orthographic projection of the support top layer in the thickness direction of the display panel, and the auxiliary electrode, the support top layer and the planarization layer surround two slots on two opposite sides of the auxiliary electrode; and ends of the second electrodes of the two adjacent light-emitting structures connected by the auxiliary electrode are in the two slots, respectively, and connected to the auxiliary electrode.

In some embodiments, the display panel further includes a pixel defining layer on a side of the planarization layer away from the substrate; and the pixel defining layer is provided with a plurality of pixel openings, and a plurality of electrode connection openings arranged at intervals and each provided between two adjacent pixel openings;
the plurality of pixel openings are in one-to-one correspondence with the plurality of light-emitting structures; and the first electrode is at least partially exposed from the pixel opening, while the luminescent material layer is at least partially in the pixel opening; and
the plurality of electrode connection openings are in one-to-one correspondence with the auxiliary electrodes; and the auxiliary electrodes are in the electrode connection openings.

In some embodiments, the display panel further includes an encapsulation layer, wherein the encapsulation layer is on a side of the light-emitting layer away from the substrate, and includes an inorganic layer covering the light-emitting layer.

In some embodiments, the luminescent material layer is a single-layer luminescent material layer, or a multi-layer luminescent material layer including at least two stacked layers.

The present application further discloses a method for manufacturing a display panel, including:
providing a substrate;
forming a planarization layer on the substrate; and
forming a light-emitting layer on a side of the planarization layer away from the substrate; wherein the light-emitting layer includes a plurality of light-emitting structures arranged at intervals and a plurality of auxiliary electrodes; wherein each light-emitting structure includes a first electrode on the planarization layer, a luminescent material layer on a side of the first electrode away from the substrate, and a second electrode on a side of the luminescent material layer away from the substrate; and the plurality of auxiliary electrodes are on the planarization layer and at least partially in direct contact with the planarization layer, and each auxiliary electrode is configured to connect second electrodes of two adjacent light-emitting structures.

In some embodiments, forming the light-emitting layer on the side of the planarization layer away from the substrate includes:
forming a first electrode material layer and an auxiliary electrode material layer on the side of the planarization layer away from the substrate;
etching the first electrode material layer and the auxiliary electrode material layer to form the first electrode and the auxiliary electrode; and
forming a luminescent material layer and a second electrode on a side of the first electrode away from the substrate.

In some embodiments, the auxiliary electrode is formed in synchronization with the first electrode; and
the auxiliary electrode is made of a same material as the first electrode.

In some embodiments, after forming the first electrode and the auxiliary electrode, the method includes:
forming two undercut grooves corresponding to each auxiliary electrode in the planarization layer, wherein the two undercut grooves corresponding to each auxiliary electrode are both partially under the auxiliary electrode, and openings of the two undercut grooves are at two opposite sides of the auxiliary electrode, respectively; and
after forming the light-emitting layer, ends of the second electrodes of the two adjacent light-emitting structures connected by the auxiliary electrode are in the two undercut grooves, respectively, connected to the auxiliary electrode.

In some embodiments, after forming the auxiliary electrode, the method includes:
forming a support top layer on a side of the auxiliary electrode away from the substrate; wherein an orthographic projection of the auxiliary electrode in a thickness direction of the display panel is within an orthographic projection of the support top layer in the thickness direction of the display panel, and the auxiliary electrode, the support top layer and the planarization layer surround two slots on two opposite sides of the auxiliary electrode;
after forming the light-emitting layer, ends of the second electrodes of the two adjacent light-emitting structures connected by the auxiliary electrode are in the two slots, respectively, connected to the auxiliary electrode.

In some embodiments, after forming the auxiliary electrode, the method includes:
forming a top layer material layer on a side of the planarization layer, the first electrode and the auxiliary electrode away from the substrate;
etching the top layer material layer in a region outside the auxiliary electrode to form a support top layer; and
etching two opposite sides of the auxiliary electrode such that an orthographic projection of the auxiliary electrode in a thickness direction of the display panel is within an orthographic projection of the support top layer in the thickness direction of the display panel, and the auxiliary electrode, the support top layer and the planarization layer surround the two slots on two opposite sides of the auxiliary electrode.

In some embodiments, after forming the first electrode and the auxiliary electrode, the method includes:
forming a pixel defining layer on a side of the planarization layer, the first electrode and the auxiliary electrode away from the substrate; wherein the pixel defining layer is provided with a plurality of pixel openings, and a plurality of electrode connection openings arranged at intervals and each provided between two adjacent pixel openings; wherein the plurality of pixel openings are in one-to-one correspondence with the plurality of light-emitting structures; the first electrode is at least partially exposed from the pixel opening, while the luminescent material layer is at least partially in the pixel opening; and the plurality of electrode connection openings are in one-to-one correspondence with the auxiliary electrodes; and the auxiliary electrodes are in the electrode connection openings.

In some embodiments, after forming the first electrode and the auxiliary electrode, the method includes:
forming a pixel defining layer on a side of the planarization layer, the first electrode and the auxiliary electrode away from the substrate; wherein the pixel defining layer is provided with a plurality of pixel openings, and a plurality of electrode connection openings arranged at intervals and each provided between two adjacent pixel openings; wherein the plurality of pixel openings are in one-to-one correspondence with the plurality of light-emitting structures; the first electrode is at least partially exposed from the pixel opening; the plurality of electrode connection openings are in one-to-one correspondence with the auxiliary electrodes; and the auxiliary electrodes are in the electrode connection openings and exposed from the electrode connection openings;
forming two undercut grooves corresponding to each auxiliary electrode in the planarization layer, wherein the two undercut grooves corresponding to each auxiliary electrode are both partially under the auxiliary electrode, and openings of the two undercut grooves are at two opposite sides of the auxiliary electrode, respectively; and
after forming the light-emitting layer, ends of the second electrodes of the two adjacent light-emitting structures connected by the auxiliary electrode are in the two undercut grooves, respectively, connected to the auxiliary electrode.

In some embodiments, at least part of the plurality of light-emitting structures are first light-emitting structures having a first emission color, and at least part of the plurality of light-emitting structures are second light-emitting structures having a second emission color; and forming the luminescent material layer and the second electrode on the side of the first electrode away from the substrate includes:
forming a luminescent material layer of the first light-emitting structures on the side of the first electrode away from the substrate;
forming second electrodes of the first light-emitting structures on a side of the luminescent material layer of the first light-emitting structures away from the substrate;
removing a luminescent material of the first light-emitting structures and the second electrodes of the first light-emitting structures in regions for forming the second light-emitting structures;
forming a luminescent material layer of the second light-emitting structures on the side of the first electrode away from the substrate in regions for forming the second light-emitting structures; and
forming second electrodes of the second light-emitting structures on a side of the luminescent material layer of the second light-emitting structures away from the substrate in regions for forming the light-emitting structures.

In some embodiments, after forming the second electrodes of the first light-emitting structures, the method includes:
forming a first inorganic layer on a side of the second electrodes of the first light-emitting structures away from the substrate;
before forming the luminescent material layer of the second light-emitting structures on the side of the first electrode away from the substrate in regions for forming the second light-emitting structures, the method further includes: removing the first inorganic layer; and
after forming the second electrodes of the second light-emitting structures, the method further includes: forming a second inorganic layer on a side of the second electrodes of the second light-emitting structures away from the substrate, wherein the second inorganic layer is connected to the first inorganic layer.

In some embodiments, all the light-emitting structures have the same emission color, and forming the luminescent material layer and the second electrode on the side of the first electrode away from the substrate includes:
sequentially forming the luminescent material layer and the second electrode on the side of the first electrode away from the substrate.

In some embodiments, after forming the light-emitting layer on the side of the planarization layer away from the substrate, the method includes:
forming an encapsulation layer on a side of the light-emitting layer away from the substrate, wherein the encapsulation layer includes an inorganic layer covering the light-emitting layer.

Compared with the existing art, the display panel and the manufacturing method therefor provided in the present application facilitate the manufacturing of the auxiliary electrode by providing both the auxiliary electrode and the first electrode on the planarization layer, thereby reducing the impact on the first electrode while the auxiliary electrode is manufactured.

It should be understood that the foregoing general description and the following detailed description are exemplary and explanatory only and are not intended to limit this specification.

### BRIEF DESCRIPTION OF FIGURES

The accompanying drawings, which are incorporated in and constitute a part of this specification, illustrate embodiments consistent with the specification and, together with the description, serve to explain the principles of the specification.

FIG. 1 is a partial cross-sectional view of a display panel according to an embodiment of the present application;

FIG. 2 is a partial cross-sectional view of another display panel according to an embodiment of the present application;

FIG. 3 is a flowchart of a method for manufacturing a display panel according to an embodiment of the present application;

FIGS. 4 to 14 are partial process diagrams for manufacturing a display panel according to an embodiment of the present application;

FIGS. 15 to 17 are partial process diagrams for manufacturing another display panel according to an embodiment of the present application;

FIGS. 18 to 20 are schematic diagrams illustrating layer structures of different light-emitting structures.

### DETAILED DESCRIPTION

Here, exemplary embodiments will be illustrated in detail, examples of which are shown in the accompanying drawings. The following description refers to the accompanying drawings in which the same numbers in different drawings represent the same or similar elements unless otherwise indicated. The implementations described in the following exemplary embodiments do not represent all implementations consistent with the specification. Rather, they are merely examples of devices and methods consistent with certain aspects of the specification, as detailed in the appended claims.

The terminology used in the present application is for the purpose of describing particular embodiments only, and is not intended to limit the present disclosure. Unless otherwise defined, the technical or scientific terms used in this specification are intended to have general meanings as understood by those of ordinary skill in the art to which the present application belongs. The words “first”, “second” and similar terms used in this specification and the claims do not denote any order, quantity, or importance, but are used merely for distinguishing different components from each other. Also, the use of the terms “a”, “an” and the like does not denote a limitation of quantity, but rather denotes the presence. The term “a plurality of” or “several” means two or more. Unless otherwise indicated, “front”, “back”, “lower”, and/or “upper”, and the like are for the convenience of description, and are not limited to one position or one spatial orientation. The word “comprise” or “include”, and the like, means that the element or item appearing in front of the word “comprise” or “include” includes the element or item listed after the word “comprise” or “include” and equivalents thereof, and does not exclude other elements or items. The terms “connected” or “coupled” and the like are not restricted to physical or mechanical connection, but may include electrical connection, either direct or indirect.

The terminology used in this specification is for the purpose of describing particular embodiments only, and is not intended to limit the present disclosure. As used in this specification and the appended claims, the singular forms “a”, “an”, and “the” are intended to include the plural forms as well, unless the context clearly indicates otherwise. It should also be understood that the term “and/or” as used herein refers to and encompasses any and all possible combinations of one or more of the associated listed items.

The present application provides a display panel and a manufacturing method therefor. The display panel includes a substrate, a planarization layer, and a light-emitting layer. The planarization layer is on the substrate. The light-emitting layer is on a side of the planarization layer away from the substrate, and includes a plurality of light-emitting structures arranged at intervals and a plurality of auxiliary electrodes. Each light-emitting structure includes a first electrode on the planarization layer, a luminescent material layer on a side of the first electrode away from the substrate, and a second electrode on a side of the luminescent material layer away from the substrate. The plurality of auxiliary electrodes are on the planarization layer and at least partially in direct contact with the planarization layer, and each auxiliary electrode is configured to connect second electrodes of two adjacent light-emitting structures. In the display panel described above, the manufacturing of the auxiliary electrode is facilitated by providing both the auxiliary electrode and the first electrode on the planarization layer, thereby reducing the impact on the first electrode while the auxiliary electrode is manufactured. The auxiliary electrode is in direct contact with the planarization layer, and, compared with an electrode structure formed by first depositing and then etching a metal layer on the pixel defining layer in the existing art, the manufacturing of the auxiliary electrode will not bring adverse effects on the pixel defining layer, the first electrode and the like due to the etching of the metal layer.

The display panel referred to in the present application may be an OLED display panel.

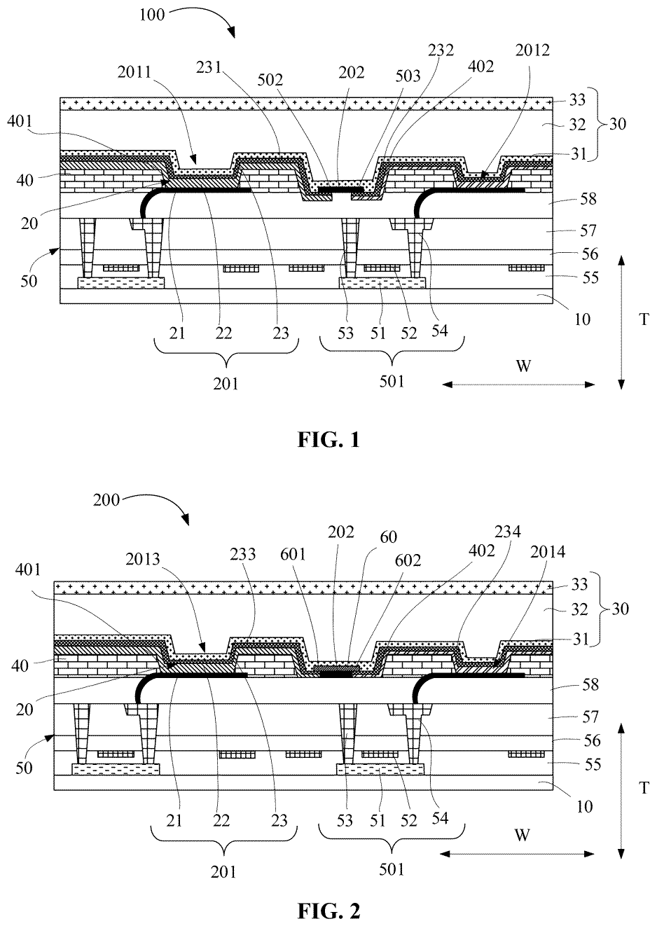

Some embodiments of the display panel and the method for manufacturing a display panel provided in the present application will be described in detail below with reference to FIGS. 1 to 20.

First, referring to FIG. 1, and in conjunction with FIGS. 2 and 18 to 20 as necessary, an embodiment of the present application provides a display panel 100. The display panel 100 includes a substrate 10, a planarization layer 58, and a light-emitting layer 20.

The planarization layer 58 is on the substrate 10.

The light-emitting layer 20 is on a side of the planarization layer 58 away from the substrate 10, and includes a plurality of light-emitting structures 201 arranged at intervals and a plurality of auxiliary electrodes 202. Each light-emitting structure 201 includes a first electrode 21 on the planarization layer 58, a luminescent material layer 22 on a side of the first electrode 21 away from the substrate 10, and a second electrode 23 on a side of the luminescent material layer 22 away from the substrate 10. The plurality of auxiliary electrodes 202 are on the planarization layer 58 and at least partially in direct contact with the planarization layer 58, and each auxiliary electrode 202 is configured to connect second electrodes 23 of two adjacent light-emitting structures 201.

Here, the first electrode 21 may be an anode, and the second electrode 23 is correspondingly a cathode. The first electrode 21 may be formed of three stacked metal layers of ITO, silver, and ITO. The second electrode 23 may be formed of two stacked metal layers of magnesium and silver.

The planarization layer 58 here may be an organic material layer.

In some embodiments, the auxiliary electrode 202 is in a same layer as the first electrode 21, which may be understood as that the two are formed synchronously by the same manufacturing process. For example, a first electrode material layer may be disposed on the planarization layer 58, and etched to form the first electrode 21 and the auxiliary electrode 202 simultaneously. The fact that the auxiliary electrode 202 is in the same layer as the first electrode 21 is beneficial to simplifying the manufacturing process of the auxiliary electrode and the first electrode, that is, simplifying the manufacturing process of the display panel.

Apparently, the first electrode and the auxiliary electrode may be formed at different steps, for example, formed by etching the first electrode material layer separately, or by etching or simultaneously etching different electrode material layers.

In some embodiments, the auxiliary electrode 202 is made of the same material as the first electrode 21, so that the two can be formed synchronously.

It will be appreciated that in some other embodiments, the two may be formed of different materials.

In some embodiments, the planarization layer 58 includes two undercut grooves 502, 503 partially under the auxiliary electrode 202 and having openings at opposite sides of the auxiliary electrode 202. Ends of the second electrodes 23 of the two adjacent light-emitting structures 201 connected by the auxiliary electrode 202 are in the two undercut grooves 502, 503, respectively, and connected to the auxiliary electrode 202.

For example, as shown in FIG. 1, the planarization layer 58 includes two undercut grooves 502, 503 partially under the auxiliary electrode 202 and having openings at opposite sides of the auxiliary electrode 202 in a width direction W. The auxiliary electrode 202 connects second electrodes 231, 232 of two adjacent light-emitting structures 2011, 2012. The second electrode 231 of the light-emitting structure 2011 has one end in the undercut groove 502, and the second electrode 232 of the light-emitting structure 2012 has one end in the undercut groove 503.

As shown in FIG. 2, in some other embodiments, the display panel 200 includes a support top layer 60 on a side of the auxiliary electrode 202 away from the substrate 10. An orthographic projection of the auxiliary electrode 202 in a thickness direction T of the display panel 200 is within an orthographic projection of the support top layer 60 in the thickness direction T of the display panel 200, and the auxiliary electrode 202, the support top layer 60 and the planarization layer 58 two slots 601, 602 on two opposite sides of the auxiliary electrode 202. Ends of the second electrodes 233, 234 of the two adjacent light-emitting structures 2013, 2014 connected by the auxiliary electrode 202 are in the two slots 601, 602, respectively, and connected to the auxiliary electrode 202.

Specifically, as shown in FIG. 2, a size of the auxiliary electrode 202 in the width direction W may be smaller than a size of the support top layer 60 in the width direction W, and two opposite ends of the auxiliary electrode 202 in the width direction W, the support top layer 60 and the planarization layer 58 surround two slots 601, 602 on two opposite sides of the auxiliary electrode 202 in the width direction W. The second electrode 233 of the light-emitting structure 2013 has one end in the slot 601, and the second electrode 234 of the light-emitting structure 2014 has one end in the slot 602.

In some embodiments, the support top layer 60 is made of an inorganic material.

Apparently, in some other embodiments, the support top layer may be of other materials.

In some embodiments, the display panel 100 further includes a pixel defining layer 40 on a side of the planarization layer 58 away from the substrate 10. The pixel defining layer 40 is provided with a plurality of pixel openings 401, and a plurality of electrode connection openings 402 arranged 402 at intervals between adjacent pixel openings 401.

The plurality of pixel openings 401 are in one-to-one correspondence with the plurality of light-emitting structures 201. The first electrode 21 is at least partially exposed from the pixel opening 401, while the luminescent material layer 22 is at least partially in the pixel opening 401.

The plurality of electrode connection openings 402 are in one-to-one correspondence with the auxiliary electrodes 202. The auxiliary electrodes 202 are in the electrode connection openings 402.

In some embodiments, the display panel 100 further includes an encapsulation layer 30. The encapsulation layer 30 is on a side of the light-emitting layer 20 away from the substrate 10, and includes an inorganic layer 31 covering the light-emitting layer 20.

As shown in FIG. 1, the encapsulation layer 30 may further include an organic layer 32 on a side of the inorganic layer 31 away from the substrate 10, and a further inorganic layer 33 on a side of the organic layer 32 away from the substrate.

As shown in FIG. 1, the display panel 100 may include a pixel driver circuit layer 50 between the substrate 10 and the light-emitting layer 20. The pixel driver circuit layer 50 includes a pixel driver circuit for driving the light-emitting structure 201. The pixel circuit includes a thin film transistor 501. The thin film transistor 501 includes an active layer 51, a gate 52 on a side of the active layer 51 away from the substrate 10, a first electrode 53, and a second electrode 54. One of the first electrode 53 or the second electrode 54 is a source, while the other is a drain. The pixel driver circuit may further include a capacitor (not shown).

The pixel driver circuit layer further includes a gate insulation layer 55, an interlayer dielectric layer 56, an interlayer dielectric layer 57, and a planarization layer 58. The gate insulation layer 55 is between the active layer 51 and the gate 52. The interlayer dielectric layer 56 is on a side of the gate 52 away from the substrate 10, and the first electrode 53 and the second electrode 54 are electrically connected to the active layer 51 via a through hole running through the gate insulation layer 55, the interlayer dielectric layer 56, and the interlayer dielectric layer 57. The planarization layer 58 is on a side of the first electrode 53 and the second electrode 54 away from the substrate 10, and covers the exposed interlayer dielectric layer 57.

It will be appreciated that the planarization layer 58 here may be a top layer of the pixel driver circuit layer 50. Apparently, in some other embodiments, the planarization layer may be another planarization layer of the pixel driver circuit layer 50 away from the substrate 10.

As shown in FIGS. 18 to 20, the luminescent material layer 22 in the present application may be a single-layer luminescent material layer. For example, as shown in FIG. 18, a layer structure of the light-emitting structure 201 may include an anode layer AE1 (corresponding to the first electrode 21), a hole transport layer HTL1, a luminescent material layer EML1, an electron transport layer ETL1, and a cathode layer CE (corresponding to the second electrode 23).

Apparently, the luminescent material layer 22 may be a multi-layer luminescent material layer including at least two stacked layers.

For example, the luminescent material layer 22 includes two stacked layers, as shown in FIG. 19. As shown in FIG. 19, the layer structure of the light-emitting structure 201 may include an anode layer AE1 (corresponding to the first electrode 21), a hole transport layer HTL1, a luminescent material layer EML11, a bonding layer CGL1, a luminescent material layer EML12, an electron transport layer ETL1, and a cathode layer CE (i.e., corresponding to the second electrode 23).

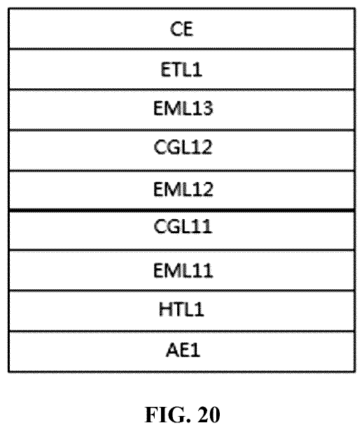

For another example, the luminescent material layer 22 includes three stacked layers, as shown in FIG. 20. As shown in FIG. 20, the layer structure of the light-emitting structure 201 may include an anode layer AE1 (corresponding to the first electrode 21), a hole transport layer HTL1, a luminescent material layer EML11, a bonding layer CGL11, a luminescent material layer EML12, a bonding layer CGL12, a luminescent material layer EML13, an electron transport layer ETL1, and a cathode layer CE (i.e., corresponding to the second electrode 23).

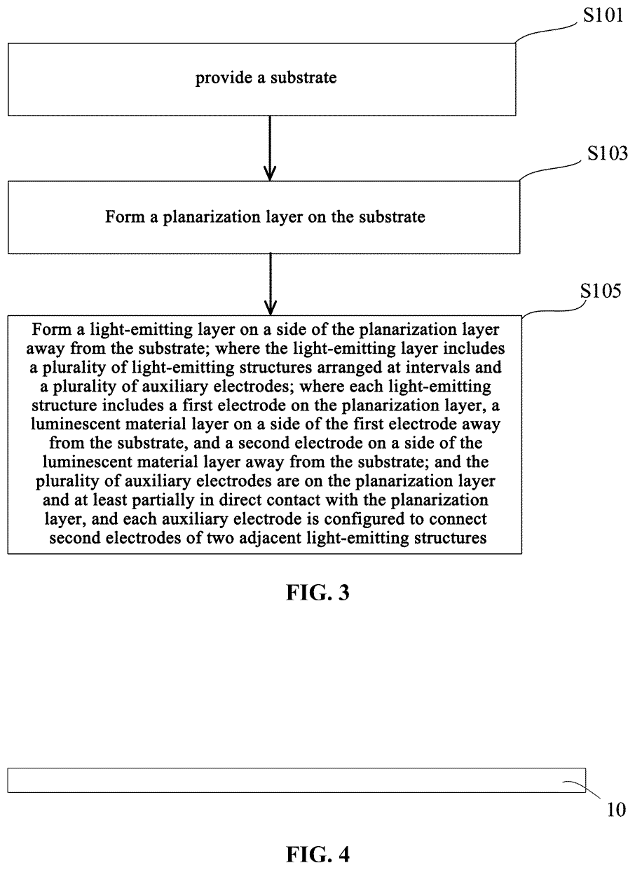

Referring to FIG. 3, and in conjunction with FIGS. 4 to 20 as necessary, the present application further provides a method for manufacturing a display panel, which includes the following steps S101 to S105.

In step S101, a substrate 10 is provided.

In step S103, a planarization layer 58 is formed on the substrate 10.

In step S105, a light-emitting layer 20 is formed on a side of the planarization layer 58 away from the substrate 10. The light-emitting layer 20 includes a plurality of light-emitting structures 201 arranged at intervals and a plurality of auxiliary electrodes 202. Each light-emitting structure 201 includes a first electrode 21 on the planarization layer 58, a luminescent material layer 22 on a side of the first electrode 21 away from the substrate 10, and a second electrode 23 on a side of the luminescent material layer 22 away from the substrate 10. The plurality of auxiliary electrodes 202 are on the planarization layer 58 and at least partially in direct contact with the planarization layer 58, and each auxiliary electrode 202 is configured to connect second electrodes 23 of two adjacent light-emitting structures 201.

As shown in FIG. 4, in step S101, a substrate 10 is provided.

The substrate 10 may be a silicon-based substrate.

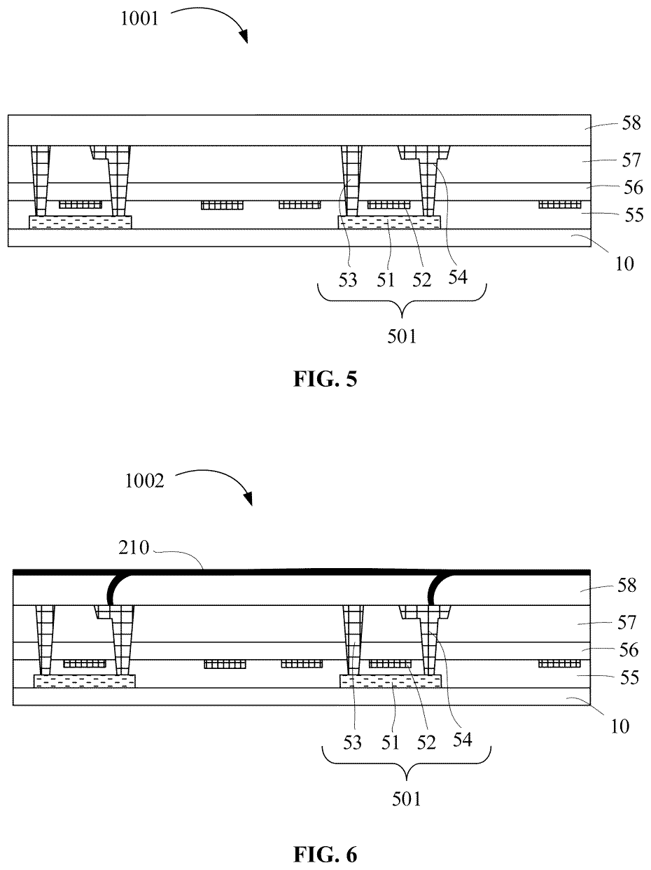

As shown in FIG. 5, in step S103, a planarization layer 58 is formed on the substrate 10.

After step S103, an intermediate structure 1001 as shown in FIG. 5 may be formed. The intermediate structure 1001 may have a driver circuit layer 50. The planarization layer 58 may be a top layer of the driver circuit layer 50. Specifically, in some embodiments, the driver circuit layer 50 may be formed on the provided substrate 10. The top layer of the driver circuit layer 50 is the planarization layer 58 formed.

Apparently, in some other embodiments, the planarization layer may be a separate film layer on a side of the driver circuit layer away from the substrate. Accordingly, the step of forming the planarization layer may be performed after forming the driver circuit layer.

In some embodiments, step S105 may include the following steps S1051 to S1053.

As shown in FIG. 6, in step S1051, a first electrode material layer and an auxiliary electrode material layer are formed on the side of the planarization layer 58 away from the substrate 10.

After step S1051, an intermediate structure 1002 as shown in FIG. 6 may be formed. In the intermediate structure 1002, the auxiliary electrode material layer and the first electrode material layer may be the same material layer, such as a first electrode material layer 210.

Apparently, in some other embodiments, the two may be different material layers.

It will be appreciated that before the first electrode material layer 210 is formed, a through hole may be provided in the planarization layer 58 to connect to a thin film transistor in the driver circuit layer. A conductive structure may be formed in the through hole while the first electrode material layer 210 is formed.

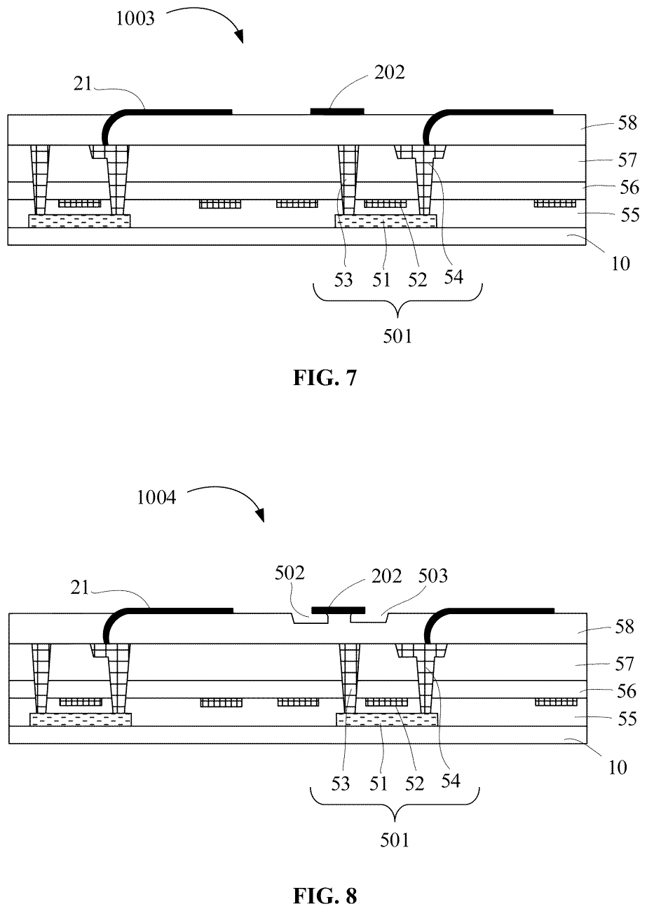

As shown in FIG. 7, in step S1052, the first electrode material layer and the auxiliary electrode material layer are etched to form the first electrode 21 and the auxiliary electrode 202.

After step S1052, an intermediate structure 1003 as shown in FIG. 7 may be formed.

In the case where the first electrode material layer and the auxiliary electrode material layer are the same, i.e., the first electrode material layer 210, the same mask may be used to perform photolithography on the first electrode material layer 210 to form the first electrode 21 and the auxiliary electrode 202.

As shown in FIGS. 8 to 14, in step S1053, a luminescent material layer 22 and a second electrode 23 are formed on a side of the first electrode 21 away from the substrate 10.

As shown in FIGS. 6 and 7, in some embodiments, the auxiliary electrode 202 is formed in synchronization with the first electrode 21.

The auxiliary electrode 202 is made of the same material as the first electrode 21.

As shown in FIG. 8, after forming the first electrode and the auxiliary electrode in step S1052, the method further includes step S10531:

In step S10531, two undercut grooves corresponding to each auxiliary electrode 202 are formed in the planarization layer 58. The two undercut grooves corresponding to each auxiliary electrode 202 are both partially under the auxiliary electrode 202, and openings of the two undercut grooves are at two opposite sides of the auxiliary electrode 202, respectively.

After step S10531, an intermediate structure 1004 as shown in FIG. 8 may be formed. In the intermediate structure 1004, the planarization layer 58 includes two undercut grooves 502, 503 partially under the auxiliary electrode 202 and having openings at opposite sides of the auxiliary electrode 202 in a width direction W.

Accordingly, after the luminescent material layer and the second electrode are formed (i.e., after the entire light-emitting layer is formed), ends of the second electrodes 23 of the two adjacent light-emitting structures 201 connected by the auxiliary electrode 202 are in the two undercut grooves, respectively, and connected to the auxiliary electrode 202.

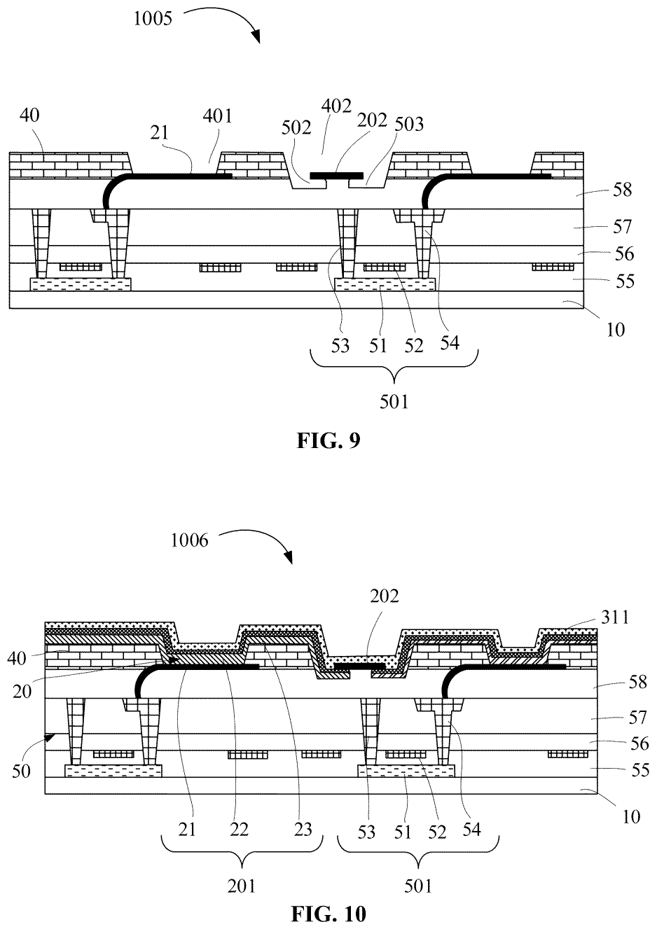

As shown in FIG. 9, after forming the first electrode and the auxiliary electrode in step S1052, specifically after step S10531, the method further includes step S10532:

In step S10532, a pixel defining layer 40 is formed on a side of the planarization layer 58, the first electrode 21 and the auxiliary electrode 202 away from the substrate 10. The pixel defining layer 40 is provided with a plurality of pixel openings 401, and a plurality of electrode connection openings 402 arranged 402 at intervals between adjacent pixel openings 401. The plurality of pixel openings 401 are in one-to-one correspondence with the plurality of light-emitting structures 201. The first electrode 21 is at least partially exposed from the pixel opening 401, while the luminescent material layer 22 is at least partially in the pixel opening 401. The plurality of electrode connection openings 402 are in one-to-one correspondence with the auxiliary electrodes 202. The auxiliary electrodes 202 are in the electrode connection openings 402. The specific structure is as shown by the intermediate structure 1005 in FIG. 9.

In some embodiments, at least part of the plurality of light-emitting structures 201 are first light-emitting structures having a first emission color, such as the light-emitting structures 2011 in FIG. 1, and at least part of the plurality of light-emitting structures are second light-emitting structures having a second emission color, such as the light-emitting structures 2012 in FIG. 1. At least some of the first and second light-emitting structures are disposed adjacent to each other.

After step S10532, the method further includes the following steps S10533 to S10537:

As shown in FIG. 10, in step S10533, a luminescent material layer 22 of the first light-emitting structures is formed on the side of the first electrode 21 away from the substrate 10.

In step S10534, second electrodes 23 of the first light-emitting structures are formed on a side of the luminescent material layer 22 of the first light-emitting structures away from the substrate 10.

After steps S10533 and S10534, an intermediate structure 1006 as shown in FIG. 10 may be formed.

In the intermediate structure 1006, the luminescent material layer 22 and the second electrodes 23 of the first light-emitting structures may be formed by forming a luminescent material layer and a material layer corresponding to the second electrodes in the whole area of the display panel, and forming the luminescent material layer and the second electrodes in the whole area by etching, respectively.

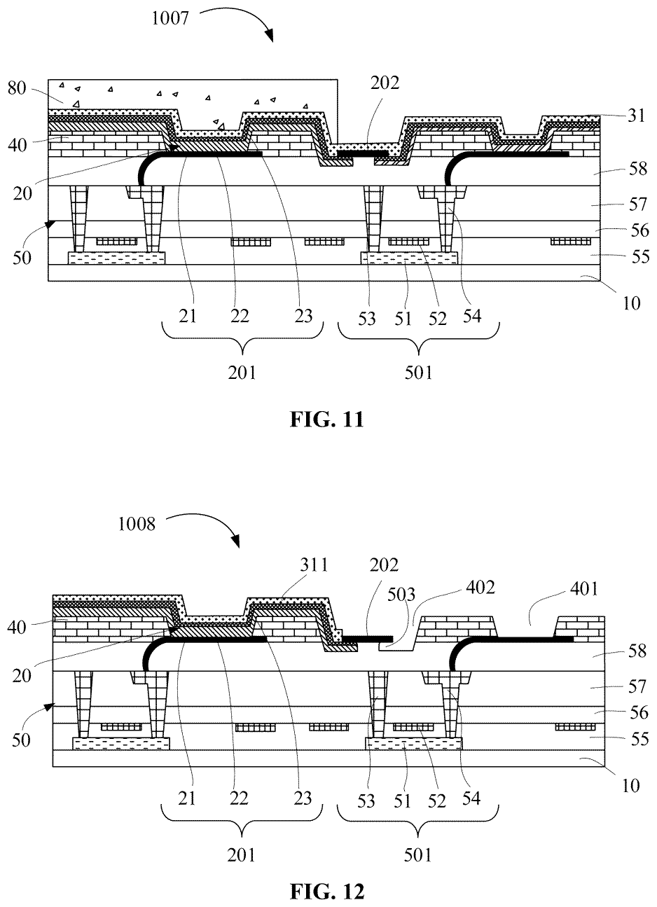

As shown in FIGS. 11 and 12, in step S10535, a luminescent material of the first light-emitting structures and the second electrodes 23 of the first light-emitting structures in regions for forming the second light-emitting structures are removed.

As shown in FIG. 11, while removing the luminescent material of the first light-emitting structures and the first electrodes of the first light-emitting structures in regions for forming the second light-emitting structures, PR glue or other protective layers may be applied above a region of the first light-emitting structures, to protect the respective structures in the region of the first light-emitting structures, such as the intermediate structure 1007 shown in FIG. 11.

It will be appreciated that, as shown in FIG. 12, while removing the luminescent material of the first light-emitting structures and the second electrodes 23 of the first light-emitting structures in regions for forming the second light-emitting structures, the luminescent material of the first light-emitting structures and the second electrodes of the first light-emitting structures in the undercut groove 502 under the auxiliary electrode 202 connecting the adjacent first and second light-emitting structures may be removed simultaneously.

After step S10535, an intermediate structure 1008 as shown in FIG. 12 may be formed. In the intermediate structure 1008, the luminescent material layer and the second electrodes in the regions for forming the second light-emitting structures are removed, and the luminescent material layer and the second electrodes in the undercut groove 502 under the auxiliary electrode 202 are also removed.

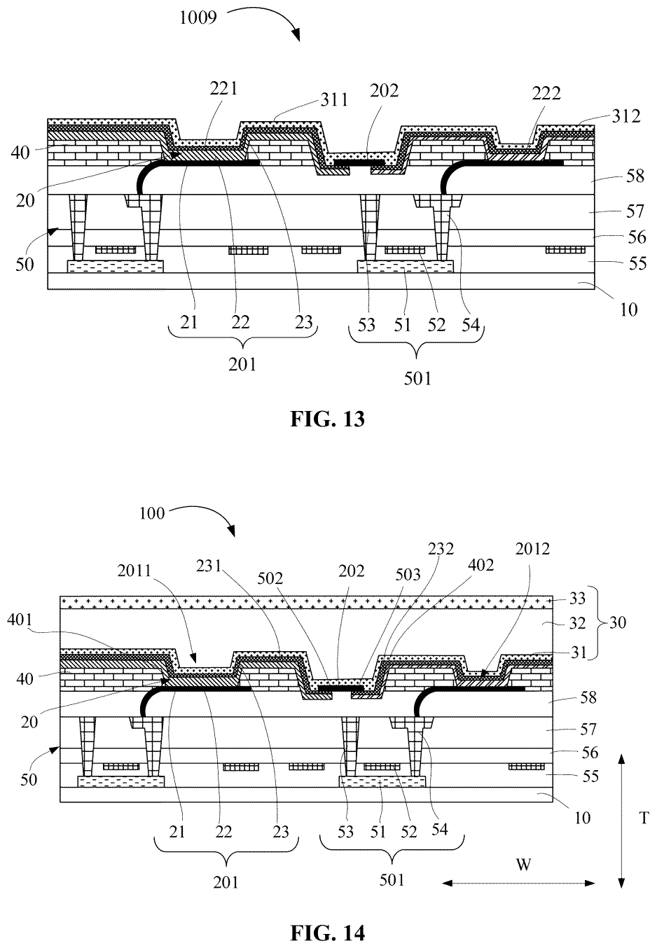

As shown in FIG. 13, in step S10536, a luminescent material layer 22 of the second light-emitting structures 201 is formed on the side of the first electrode 21 away from the substrate 10 in regions for forming the second light-emitting structures 201.

In step S10537, second electrodes 23 of the second light-emitting structures 201 are formed on a side of the luminescent material layer 22 of the second light-emitting structures 201 away from the substrate 10 in regions for forming the light-emitting structures 201.

After steps S10536 and S10537, an intermediate structure 1009 as shown in FIG. 13 may be formed. In this intermediate structure, the second electrodes of the first light-emitting structure and the second light-emitting structure at two opposite sides of the auxiliary electrode 202 in the width direction W are connected through the auxiliary electrode 202. In addition, the luminescent material layers of the first and second light-emitting structures are different.

Steps S10536 and S10537 are similar to steps S10533 and S10534 described above.

It will be appreciated that a further part of the plurality of light-emitting structures may be third light-emitting structures having a third emission color. Accordingly, in step S10535, a luminescent material of the first light-emitting structures and the second electrodes 23 of the first light-emitting structures in regions for forming the third light-emitting structures may be removed. While steps S10536 and S10537 are performed, the second light-emitting structures are formed in the regions for forming the third light-emitting structures. Accordingly, steps similar to steps S10535 to S10537 may be repeated to form third light-emitting structures in the regions for forming the third light-emitting structures.

Here, the first emission color, the second emission color, and the third emission color may each be one of red, green or blue, respectively.

Apparently, the light-emitting structures of the display panel may have only two types of light-emitting structures having the first emission color and the second emission color. Accordingly, the first emission color and the second emission color may be any two of red, blue and green.

In addition, in some other embodiments, all light-emitting structures may have the same emission color. Accordingly, after step S1052, especially after step S10532, the method includes the following step S1530:

In step S1530, the luminescent material layer and the second electrode are sequentially formed on the side of the first electrode away from the substrate.

This step S1530 may be similar to steps S10533 and S10534. In this embodiment, after the luminescent material layer and the second electrode are formed, subsequent film layers or structures may be directly provided.

In some embodiments, after forming the second electrodes 23 of the first light-emitting structures 201 in step S1052, specifically after step S10534, the method further includes the following step S10538:

In step S10538, a first inorganic layer, such as the inorganic layer 311 in FIG. 10, is formed on a side of the second electrodes 23 of the first light-emitting structures 201 away from the substrate 10.

Accordingly, before forming the luminescent material layer 22 of the second light-emitting structures 201 in regions for forming the second light-emitting structures 201 on the side of the first electrode 21 away from the substrate 10, the method further includes: removing the first inorganic layer 311, for example, as shown in FIG. 12. The step of removing the first inorganic layer 311 may be performed synchronously with, or before, step S10535.

Accordingly, after forming the second electrodes 23 of the second light-emitting structures 201, the method further includes the following step S10539:

In step S10539, a second inorganic layer 312 is formed on a side of the second electrodes 23 of the second light-emitting structures 201 away from the substrate 10. The second inorganic layer 312 is connected to the first inorganic layer 311 to form a continuous inorganic layer 31, for example, as shown in FIG. 13.

In the case where all light-emitting structures have the same emission color, after the luminescent material layer and the second electrode are formed, an encapsulation layer 30 may be directly formed on a side of the light-emitting layer 20 away from the substrate 10. The encapsulation layer 30 includes an inorganic layer covering the light-emitting layer 20.

It should be noted that, in some other embodiments, the manufacturing sequence of steps S10531 and S10532 may be interchanged. That is, after step S1052, the pixel defining layer is formed before the undercut grooves 502 and 503.

Here, taking the formation of the undercut grooves 502 and 503 as an example for illustration, in some embodiments, after forming the first electrode and the auxiliary electrode in step S1052, the method further includes steps S10531′ and S10532′:

In step S10531′, a pixel defining layer is formed on a side of the planarization layer, the first electrode and the auxiliary electrode away from the substrate. The pixel defining layer is provided with a plurality of pixel openings, and a plurality of electrode connection openings arranged at intervals and each provided between two adjacent pixel openings. The plurality of pixel openings are in one-to-one correspondence with the plurality of light-emitting structures. The first electrode is at least partially exposed from the pixel opening. The plurality of electrode connection openings are in one-to-one correspondence with the auxiliary electrodes. The auxiliary electrodes are in the electrode connection openings and exposed from the electrode connection openings;

In step S10532′, two undercut grooves corresponding to each auxiliary electrode are formed in the planarization layer. The two undercut grooves corresponding to each auxiliary electrode are both partially under the auxiliary electrode, and openings of the two undercut grooves are at two opposite sides of the auxiliary electrode, respectively.

After the light-emitting layer is formed, ends of the second electrodes of the two adjacent light-emitting structures connected by the auxiliary electrode are in the two undercut grooves, respectively, and connected to the auxiliary electrode.

It will be appreciated that in this embodiment, after step S10532′, step S10533 and other subsequent steps may be performed, and specific details may refer to the corresponding steps described above.

It will be appreciated that in some other embodiments, instead of providing undercut grooves in the planarization layer 58, slots may be formed on a side of the planarization layer 58 away from the substrate 10.

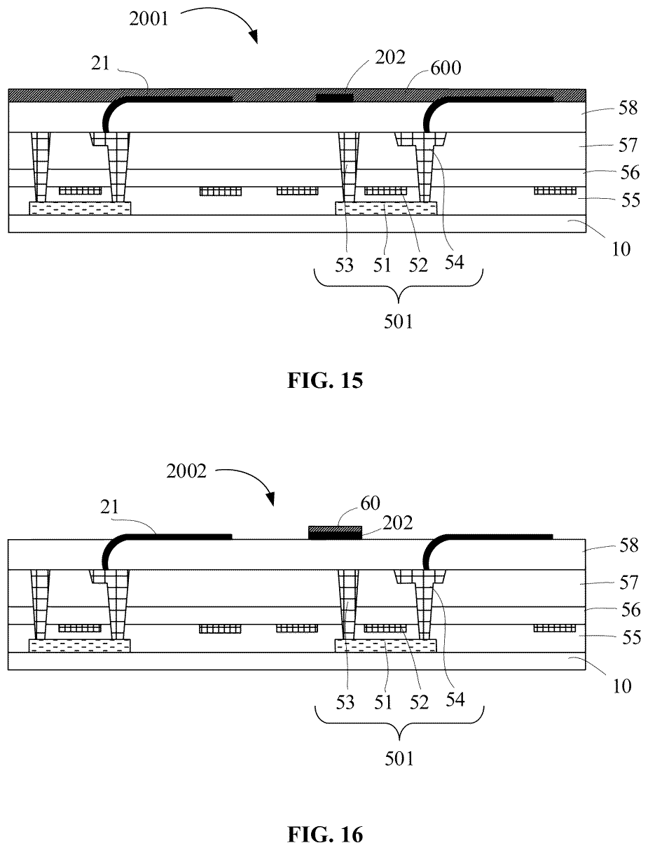

With reference to FIGS. 15 to 17, in some other embodiments, after forming the auxiliary electrode 202 in step S1052, the method includes step S1054:

In step S1054, a support top layer 60 is formed on a side of the auxiliary electrode 202 away from the substrate 10. An orthographic projection of the auxiliary electrode 202 in a thickness direction T of the display panel is within an orthographic projection of the support top layer 60 in the thickness direction T of the display panel, and the auxiliary electrode 202, the support top layer 60 and the planarization layer 58 surround two slots 601, 602 on two opposite sides of the auxiliary electrode 202.

Accordingly, after the entire light-emitting layer 20 is formed, ends of the second electrodes 23 of the two adjacent light-emitting structures 201 connected by the auxiliary electrode 202 are in the two slots, respectively, and connected to the auxiliary electrode 202.

Referring to FIGS. 15 to 17, after forming the auxiliary electrode 202 in step S1052, step S1054 may specifically include steps S10541 to S10543:

As shown in FIG. 15, in step S10541, a top layer material layer 600 is formed on a side of the planarization layer 58, the first electrode 21 and the auxiliary electrode 202 away from the substrate 10, to form an intermediate structure 2001 as shown in FIG. 15.

As shown in FIG. 16, in step S10542, the top layer material layer in a region outside the auxiliary electrode 202 is etched to form a support top layer 60, so that an intermediate structure 2002 as shown in FIG. 16 may be formed.

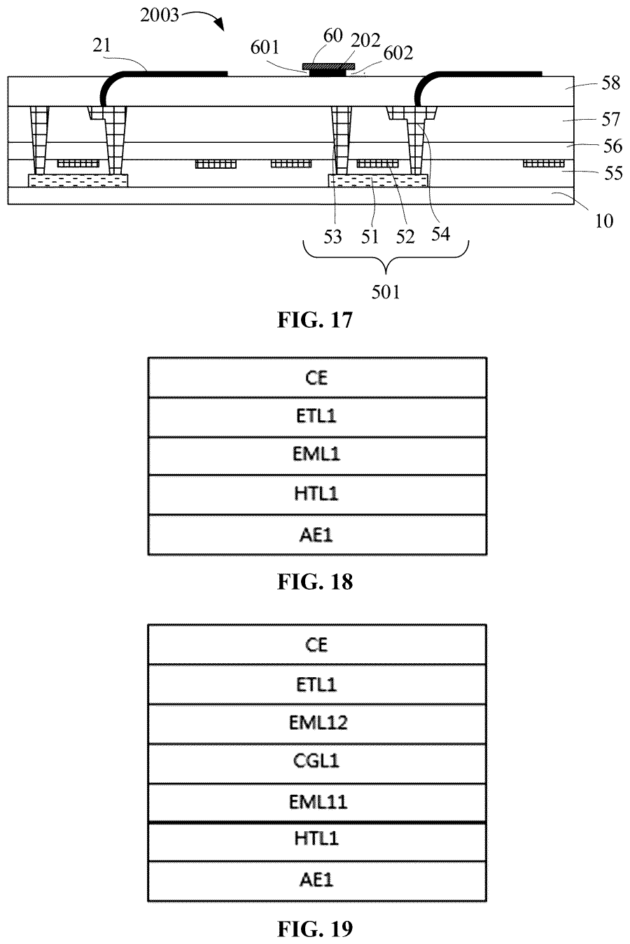

As shown in FIG. 17, in step S10543, two opposite sides of the auxiliary electrode 202 are etched such that an orthographic projection of the auxiliary electrode 202 in a thickness direction T of the display panel is within an orthographic projection of the support top layer 60 in the thickness direction T of the display panel, and the auxiliary electrode 202, the support top layer 60 and the planarization layer 58 surround two slots 601, 602 on two opposite sides of the auxiliary electrode 202, forming an intermediate structure 2003 as shown in FIG. 17.

The subsequent steps of providing the luminescent material layer, the second electrode, the encapsulation layer, and the like in this embodiment are similar to those in the above implementations of providing the undercut grooves 502, 503, and reference may be made to the above description, which is not repeated here.

Other implementations of this specification will be apparent to those skilled in the art from consideration of the description and practice of the present application disclosed herein. The specification is intended to cover any variations, uses, or adaptations of the specification which follow general principles of the specification and include common knowledge or conventional technical means in the art that are not disclosed herein. The description and the embodiments are intended to be considered as exemplary only, with a true scope and spirit of the specification being indicated by the following claims.

It will be appreciated that the specification is not limited to the precise structures as described above and shown in the drawings, and that various modifications and changes may be made without departing from the scope of the present disclosure. The scope of the specification is defined only by the appended claims.

The above are merely preferred embodiments of the specification and not intended to limit the specification. Any amendments, equivalent substitutions, improvements, and the like within the principle of the specification are all included in the scope of the protection defined by the appended claims of the specification.

1. A display panel, comprising:
a substrate;
a planarization layer on the substrate;
a light-emitting layer on a side of the planarization layer away from the substrate, comprising a plurality of light-emitting structures arranged at intervals and a plurality of auxiliary electrodes;
wherein each light-emitting structure comprises a first electrode on the planarization layer, a luminescent material layer on a side of the first electrode away from the substrate, and a second electrode on a side of the luminescent material layer away from the substrate; and the plurality of auxiliary electrodes are on the planarization layer and at least partially in direct contact with the planarization layer, and each auxiliary electrode is configured to connect second electrodes of two adjacent light-emitting structures.

2. The display panel according to claim 1, wherein the auxiliary electrode is in a same layer as the first electrode; and
the auxiliary electrode is made of a same material as the first electrode.

3. The display panel according to claim 1, wherein the planarization layer comprises two undercut grooves partially under the auxiliary electrode and having openings at opposite sides of the auxiliary electrode; and ends of the second electrodes of the two adjacent light-emitting structures connected by the auxiliary electrode are in the two undercut grooves, respectively, and connected to the auxiliary electrode.

4. The display panel according to claim 1, wherein the display panel comprises a support top layer on a side of the auxiliary electrode away from the substrate, an orthographic projection of the auxiliary electrode in a thickness direction of the display panel is within an orthographic projection of the support top layer in the thickness direction of the display panel, and the auxiliary electrode, the support top layer and the planarization layer surround two slots on two opposite sides of the auxiliary electrode; and ends of the second electrodes of the two adjacent light-emitting structures connected by the auxiliary electrode are in the two slots, respectively, and connected to the auxiliary electrode.

5. The display panel according to claim 1, wherein the display panel further comprises a pixel defining layer on a side of the planarization layer away from the substrate;
and the pixel defining layer is provided with a plurality of pixel openings, and a plurality of electrode connection openings arranged at intervals and each provided between two adjacent pixel openings;
the plurality of pixel openings are in one-to-one correspondence with the plurality of light-emitting structures; and the first electrode is at least partially exposed from the pixel opening, while the luminescent material layer is at least partially in the pixel opening; and
the plurality of electrode connection openings are in one-to-one correspondence with the auxiliary electrodes; and the auxiliary electrodes are in the electrode connection openings.

6. The display panel according to-any claim 1, wherein the display panel further comprises an encapsulation layer, wherein the encapsulation layer is on a side of the light-emitting layer away from the substrate, and comprises an inorganic layer covering the light-emitting layer.

7. The display panel according claim 1, wherein the luminescent material layer is a single-layer luminescent material layer, or a multi-layer luminescent material layer comprising at least two stacked layers.

8. A method for manufacturing a display panel, wherein the method comprises:
providing a substrate;
forming a planarization layer on the substrate; and
forming a light-emitting layer on a side of the planarization layer away from the substrate;
wherein the light-emitting layer comprises a plurality of light-emitting structures arranged at intervals and a plurality of auxiliary electrodes; each light-emitting structure comprises a first electrode on the planarization layer, a luminescent material layer on a side of the first electrode away from the substrate, and a second electrode on a side of the luminescent material layer away from the substrate; and the plurality of auxiliary electrodes are on the planarization layer and at least partially in direct contact with the planarization layer, and each auxiliary electrode is configured to connect second electrodes of two adjacent light-emitting structures.

9. The method for manufacturing a display panel according to claim 8, wherein forming the light-emitting layer on the side of the planarization layer away from the substrate comprises:
forming a first electrode material layer and an auxiliary electrode material layer on the side of the planarization layer away from the substrate;
etching the first electrode material layer and the auxiliary electrode material layer to form the first electrode and the auxiliary electrode; and
forming a luminescent material layer and a second electrode on a side of the first electrode away from the substrate.

10. The method for manufacturing a display panel according to claim 9, wherein the auxiliary electrode is formed in synchronization with the first electrode; and
the auxiliary electrode is made of a same material as the first electrode.

11. The method for manufacturing a display panel according to claim 9, wherein after forming the first electrode and the auxiliary electrode, the method comprises:
forming two undercut grooves corresponding to each auxiliary electrode in the planarization layer, wherein the two undercut grooves corresponding to each auxiliary electrode are both partially under the auxiliary electrode, and openings of the two undercut grooves are at two opposite sides of the auxiliary electrode, respectively; and
after forming the light-emitting layer, ends of the second electrodes of the two adjacent light-emitting structures connected by the auxiliary electrode are in the two undercut grooves, respectively, connected to the auxiliary electrode.

12. The method for manufacturing a display panel according to claim 9, wherein after forming the auxiliary electrode, the method comprises:
forming a support top layer on a side of the auxiliary electrode away from the substrate;
wherein an orthographic projection of the auxiliary electrode in a thickness direction of the display panel is within an orthographic projection of the support top layer in the thickness direction of the display panel, and the auxiliary electrode, the support top layer and the planarization layer surround two slots on two opposite sides of the auxiliary electrode; and
after forming the light-emitting layer, ends of the second electrodes of the two adjacent light-emitting structures connected by the auxiliary electrode are in the two slots, respectively, connected to the auxiliary electrode.

13. The method for manufacturing a display panel according to claim 12, wherein after forming the auxiliary electrode, the method comprises:
forming a top layer material layer on a side of the planarization layer, the first electrode and the auxiliary electrode away from the substrate;
etching the top layer material layer in a region outside the auxiliary electrode to form a support top layer; and
etching two opposite sides of the auxiliary electrode such that an orthographic projection of the auxiliary electrode in a thickness direction of the display panel is within an orthographic projection of the support top layer in the thickness direction of the display panel, and the auxiliary electrode, the support top layer and the planarization layer surround the two slots on two opposite sides of the auxiliary electrode.

14. The method for manufacturing a display panel according to claim 9, wherein after forming the first electrode and the auxiliary electrode, the method comprises:
forming a pixel defining layer on a side of the planarization layer, the first electrode and the auxiliary electrode away from the substrate; wherein the pixel defining layer is provided with a plurality of pixel openings, and a plurality of electrode connection openings arranged at intervals and each provided between two adjacent pixel openings; wherein the plurality of pixel openings are in one-to-one correspondence with the plurality of light-emitting structures; the first electrode is at least partially exposed from the pixel opening, while the luminescent material layer is at least partially in the pixel opening; and the plurality of electrode connection openings are in one-to-one correspondence with the auxiliary electrodes; and the auxiliary electrodes are in the electrode connection openings.

15. The method for manufacturing a display panel according to claim 9, wherein after forming the first electrode and the auxiliary electrode, the method comprises:
forming a pixel defining layer on a side of the planarization layer, the first electrode and the auxiliary electrode away from the substrate; wherein the pixel defining layer is provided with a plurality of pixel openings, and a plurality of electrode connection openings arranged at intervals and each provided between two adjacent pixel openings; wherein the plurality of pixel openings are in one-to-one correspondence with the plurality of light-emitting structures; the first electrode is at least partially exposed from the pixel opening; the plurality of electrode connection openings are in one-to-one correspondence with the auxiliary electrodes; and the auxiliary electrodes are in the electrode connection openings and exposed from the electrode connection openings;
forming two undercut grooves corresponding to each auxiliary electrode in the planarization layer, wherein the two undercut grooves corresponding to each auxiliary electrode are both partially under the auxiliary electrode, and openings of the two undercut grooves are at two opposite sides of the auxiliary electrode, respectively; and
after forming the light-emitting layer, ends of the second electrodes of the two adjacent light-emitting structures connected by the auxiliary electrode are in the two undercut grooves, respectively, connected to the auxiliary electrode.

16. The method for manufacturing a display panel according to claim 9, wherein at least part of the plurality of light-emitting structures are first light-emitting structures having a first emission color, and at least part of the plurality of light-emitting structures are second light-emitting structures having a second emission color; and forming the luminescent material layer and the second electrode on the side of the first electrode away from the substrate comprises:
forming a luminescent material layer of the first light-emitting structures on the side of the first electrode away from the substrate;
forming second electrodes of the first light-emitting structures on a side of the luminescent material layer of the first light-emitting structures away from the substrate;
removing a luminescent material of the first light-emitting structures and the second electrodes of the first light-emitting structures in regions for forming the second light-emitting structures;
forming a luminescent material layer of the second light-emitting structures on the side of the first electrode away from the substrate in regions for forming the second light-emitting structures; and
forming second electrodes of the second light-emitting structures on a side of the luminescent material layer of the second light-emitting structures away from the substrate in regions for forming the second light-emitting structures.

17. The method for manufacturing a display panel according to claim 16, wherein after forming the second electrodes of the first light-emitting structures, the method comprises:
forming a first inorganic layer on a side of the second electrodes of the first light-emitting structures away from the substrate;
before forming the luminescent material layer of the second light-emitting structures on the side of the first electrode away from the substrate in regions for forming the second light-emitting structures, the method further comprises: removing the first inorganic layer; and
after forming the second electrodes of the second light-emitting structures, the method further comprises: forming a second inorganic layer on a side of the second electrodes of the second light-emitting structures away from the substrate, wherein the second inorganic layer is connected to the first inorganic layer.

18. The method for manufacturing a display panel according to claim 9, wherein all the light-emitting structures have the same emission color, and forming the luminescent material layer and the second electrode on the side of the first electrode away from the substrate comprises:
sequentially forming the luminescent material layer and the second electrode on the side of the first electrode away from the substrate.

19. The method for manufacturing a display panel according to claim 18, wherein after forming the light-emitting layer on the side of the planarization layer away from the substrate, the method comprises:
forming an encapsulation layer on a side of the light-emitting layer away from the substrate, wherein the encapsulation layer comprises an inorganic layer covering the light-emitting layer.
